(19) United States
(12) Patent Application Publication
(10) Pub. No.: US 2007/0141736 A1
(43) Pub. Date: Jun. 21, 2007

(54) Field emission device with self-aligned gate electrode structure, and method of manufacturing same

(76) Inventors: Liesbeth Van Pieterson, Eindhoven (NL); Siebe Tjerk De Zwart, Eindhoven (NL); Hugo Matthieu Visser, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/530,308

(22) PCT Filed: Sep. 12, 2003
(86) PCT No.: PCT/IB03/04028

§ 371 Date: Apr. 4, 2005

(30) Foreign Application Priority Data
Oct. 7, 2002 (EP) 02079152.1

(51) Int. Cl. H01L 21/00; H01L 21/331; H01L 29/74; H01L 29/51; H01L 31/111

(52) U.S. Cl. 438/20; 438/342; 257/164

(57) ABSTRACT

The invention relates to a field emission device, and a method of manufacturing same. The field emission device comprises a gate electrode (140, 340, 440) which is provided with a pattern of electron passing apertures (135, 335, 435). The gate electrode (140, 340, 440) is arranged near particles (110, 310, 410) distributed on a substrate (125, 325, 425), at least a part of said particles (110, 310, 410) being arranged for emitting electrons. By means of the gate electrode (140, 340, 440), an electric field is applicable by means of which emitting particles emit electrons. Particularly good electron emission is obtained, because the pattern of apertures (135, 335, 435) is similar to the distribution of particles (110, 310, 410) on the substrate. This is achieved by means of the manufacturing method, in which the particles (110, 310, 410) are used in an illumination step to mask regions (155, 355) of a photo layer (150, 352). Thus, a pattern is obtained in the photo layer (150, 352), which can be used to obtain a similar pattern in the gate electrode (140, 340, 440) with relative case.

The invention relates to a method of manufacturing a field emission device.

The invention further relates to a field emission device, comprising:
a distribution of particles on a substrate, at least a part of said particles being arranged for emitting electrons and
a gate electrode near said particles, said gate electrode being provided with a pattern of apertures for passing emitted electrons.

The field emission device may be used as an electron source for a flat-panel type display, the so-called Field Emission Display (FED). The FED is a vacuum electronic device, sharing many common features with the well-known Cathode Ray Tube (CRT), such as low manufacturing costs, good contrast and viewing angle and no required back-lighting.

Field emission is a quantum-mechanical phenomenon in which electrons tunnel through a potential barrier at an outer surface of a suitable emitter, as a result of an applied electric field. The presence of the electric field makes the width of the potential barrier at said outer surface finite, so that this potential barrier is permeable for electrons. Thus, electrons may be emitted from the field emitter.

The substrate is generally provided with a conductive layer forming a cathode electrode, on top of which a plurality of field emitters are provided. The field emitters can be provided by a distribution of particles on the substrate.

For example, suitable field emitters include diamond, carbon nanotubes, graphite particulate emitter inks, as known from U.S. Pat. No. 6,097,139, or a compound such as lantane hexaboride (LaB₆) or yttrium hexaboride (YB₆).

A gate electrode is present near the emitter, for applying the required electric field. For this purpose a voltage difference is applied between the cathode electrode and the gate electrode, which is separated from the cathode electrode by a vacuum or preferably an insulating layer. By means of the electric field, particles between the cathode electrode and the gate electrode are activated and emit electrons.

To ensure electron emission from the device, the gate electrode is provided with a plurality of (sub)micron apertures for passing the emitted electrons. In field emission devices such as the device known from the aforementioned U.S. Pat. No. 6,097,139, the apertures in the gate electrode structure are formed using expensive and state-of-the-art lithography.

However, when applying the known gate electrode structure, the number of particles that emits a significant amount of electrons is relatively low, and therefore electron emission from the device is insufficient.

It is therefore a problem to construct a field emission device that has sufficiently high electron emission.

It is an object of the invention to provide a method of manufacturing a field emission device that has an improved electron emission.

This object is achieved by a method of manufacturing a field emission device according to the invention as specified in the independent claim 1.

The invention is based on the recognition that the particles deposited on the substrate may generally be used as a shading mask. The manufacturing of the device therefore comprises an illumination step, whereby light impinges in the device from the substrate side. The light passes the substrate, since the substrate is transparent, “transparent” within the concept of the invention meaning transparent to the light that is used during the illumination step of the manufacturing method.

Therefore, light passes unhindered through parts of the device where no particles are provided. However, at the location of the particles, the incident light is blocked, so that regions of the photo layer are in the shadow of the particles and not illuminated. Thus, the photo layer is masked.

As a consequence, the photo layer is removable either in the shaded regions (positive photo layer) or outside the shaded regions (negative photo layer) by means of a subsequent etching step. The etched photo layer therefore shows a pattern that matches the distribution of the particles on the substrate, and in a subsequent step a gate electrode provided with electron passing apertures in a similar pattern is formed with relative ease

In a conventional manufacturing method, it is difficult to position the apertures in the gate structure well relative to the particles, since the distribution of the particles is generally unordered, or even random. By virtue of the invention, a gate electrode is obtained, the apertures of which are automatically aligned with the disorderly distributed particles.

By means of this gate electrode, in operation a relatively high electric field is applied over the entire outer surfaces of the active particles. Therefore, the active particles emit a relatively large number of electrons, and thus the electron emission by the device according to the invention is increased significantly.

Moreover, the manufacturing method according to the present invention does not rely on conventional lithography to form the (sub)micron apertures in the gate electrode. This is an advantage, since conventional lithography on this scale is troublesome and relatively expensive.

In a first preferred embodiment, the photo layer comprises a positive photo resist. The gate electrode is formed from a conductive layer, and the positive photo layer is deposited on top of said conductive layer, the etching step comprising the further steps of removing the shaded regions of said positive photo layer and forming the plurality of apertures in the conductive layer adjacent to the removed shaded regions.

The etching of the photo layer is continued into the conductive layer. Thus, apertures are provided in the conductive layer, which are automatically aligned with the shaded regions of the photo layer, and thus with the particles. The gate electrode that is formed has a pattern of self-aligned apertures that matches the distribution of the emitter particles particularly well. The field emission device thus manufactured operates particularly efficiently and has relatively high electron emission.

Preferably, the method comprises the step of heating the conductive layer during a preselected time.

Generally, this heating takes place right after the layer is deposited. Heating the conductive layer allows for an improved control over the size of the apertures in the gate structure. If no heating takes place, or the heating time is relatively short, the etching causes apertures to be formed in the conductive layer that are large in comparison with the particles. This is advantageous with respect to short circuits and can be used to control the emission properties.

However, if the density of the particles on the substrate surface is relatively high, it is more advantageous to have apertures in the gate electrode that have a similar size to the particles. Otherwise, apertures corresponding to adjacent emitter particles overlap and too large a part of the conductive layer is removed, which causes a deterioration of the emission properties. In this situation it is desirable to heat the conductive layer during a relatively long time, which causes smaller apertures to be formed. If desired, the aperture size can be made approximately equal to the size of the emitter particles.

In a second preferred embodiment of the method, the photo layer comprises a negative photo resist. The second preferred embodiment is further characterized in that an insulating layer is provided at least partially covering the particles, and the negative photo layer is deposited on top of said insulating layer, whereby the etching step comprises the further steps of removing parts of said negative photo layer outside the shaded regions exposing parts of said insulating layer, and forming the gate electrode structure by depositing electrode material on said exposed parts of said insulating layer.

Such an insulating layer is known from the state of the art, its function is to enhance the electric field between the cathode electrode and the gate electrode thereby improving the electron emission properties of the device.

The shaded regions of the negative photo layer remain on the device until after the gate electrode is formed, and are then easily removable, for instance by conventional washing.

The second embodiment has the advantage that there is more freedom in choosing the material forming the gate electrode, since the conductive material no longer has to be transparent to the light used in the illumination step. This opens the possibility of using for example an aluminum gate electrode.

It is a further object of the invention to provide a field emission device that has an improved electron emission. This further object is achieved by means of a field emission device according to the invention as specified in the independent Claim 5, and is thus characterized in that the pattern of the apertures in the gate electrode is similar to the distribution of the particles on the substrate.

Such a field emission device is obtained using the manufacturing method as described earlier. By virtue of this method, the apertures of the gate electrode are self-aligned with the emitter particles, and good electron emission is obtained.

A field emission device in which the apertures of the gate electrode are arranged in a unordered pattern is known from European patent 0 700 065. Herein, the apertures are formed by means of masking particles. At the location of the masking particles, no conductive layer is deposited. However, in that device, the masking particles are larger than the emitter particles, so that also gate electrode apertures are formed that are large compared to the particles. Moreover, the pattern of the gate apertures is not similar to the distribution of the emitter particles on the substrate. Thus, the gate electrode in that device is less efficient, and electron emission is lower than in the field emission device according to the present invention.

Preferably, an insulating layer is provided between the substrate and the gate electrode, said insulating layer at least partially covering the particles.

Preferably, the insulating layer is recessed substantially at the location of the particles. This arrangement has the advantage that, within the device, the emitted electrons largely travel through vacuum instead of through the insulating layer, so that electrons are more easily released from the field emission device. Most preferably, a relatively thin insulating layer remains over the particles on the substrate, the thickness of said thin layer being for instance 30 or 50 nanometers.

The recessing of the insulating layer may be achieved in the first embodiment by continuing the etching step to at least partially remove the insulating layer adjacent to the apertures formed in the gate electrode. In the second embodiment, after forming the gate electrode, this may be used as a mask for a subsequent second etching step wherein the insulating layer adjacent to the apertures in the gate electrode is removed.

Preferably, the substrate is transparent and comprises a transparent cathode electrode. A preferred and suitable material for the cathode electrode is then indium tin oxide (ITO). The same material may be used as the conductive layer for forming the gate electrode in the first embodiment of the manufacturing method.

The particles distributed on the substrate may comprise any sort of sufficiently large particles that show field emission of electrons, but preferably, the particles comprise graphite-based field emitter, or carbon nanotubes.

Among other applications, carbon nanotubes are applied as emitters for a field emission device, as is disclosed for instance in U.S. Pat. No. 6,239,547. However, they cannot be applied per se in the present invention, since their diameter is about two orders of magnitude smaller than the wavelength of the light that is used during illumination. Thus, individual carbon nanotubes by themselves are not able to form a mask.

However, it is possible to deposit the carbon nanotubes in clusters which, as a whole, are sufficiently large to block the incident light, or, more preferably, the carbon nanotubes are deposited by means of a catalytic growing process. Thereby, first precursor particles such as cobalt (Co) or nickel (Ni) are distributed on the substrate whereafter the device is formed as described earlier. These precusor particles act as the masking particles during illumination. After forming the gate structure, the carbon nanotubes are grown from the precursor particles.

These and other aspects of the present invention will be apparent from and elucidated with reference to the appended drawings.

### IN THE DRAWINGS

FIGS. 1A-1E illustrate a first embodiment of the manufacturing method according to the invention;

FIGS. 2A-2C show top views of an embodiment of the field emission device;

FIGS. 3A-3F illustrate a second embodiment of the method;

FIG. 4 shows a further embodiment of a field emission device according to the invention;

FIG. 5 shows an embodiment of a field emission display (FED).

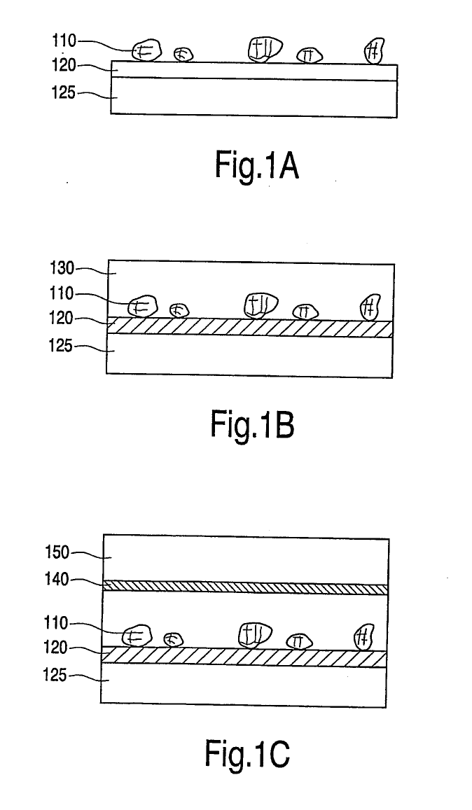

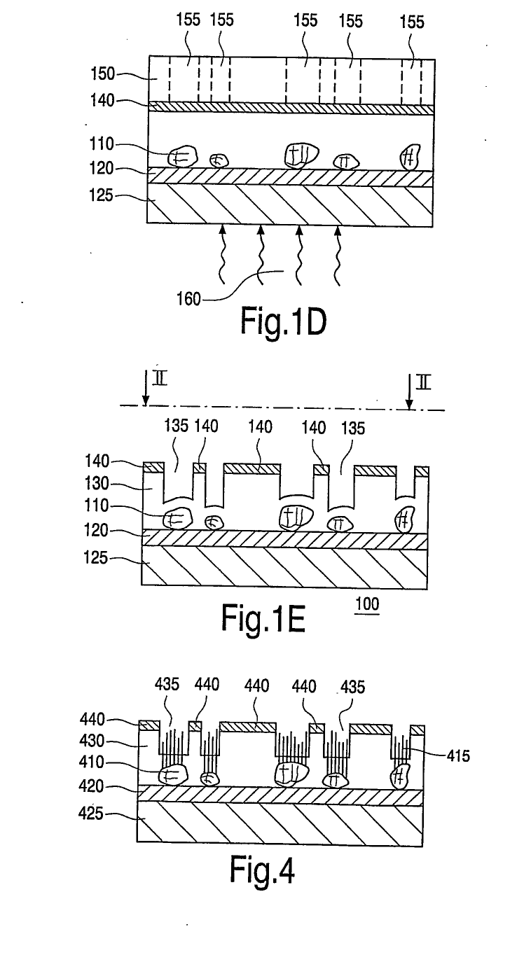

A first embodiment of the manufacturing method according to the invention is illustrated by FIGS. 1A-1E. By applying the method, a field emission device 100 having a self-aligned gate electrode structure 140 is obtained. The apertures 135 in the gate electrode structure 140 and the insulating layer 130 are similarly sized as the emitter particles 110, and are particularly well aligned with said particles.

In a first step (FIG. 1A), a transparent substrate 125 of for example glass is provided with a transparent cathode electrode 120, for instance by depositing a layer of indium tin oxide (ITO). On top of the cathode electrode 120, and in electrical contact therewith, particles 110 are distributed, for instance using an electrophoretic deposition process. The deposited particles 110 generally show an unordered distribution. In this embodiment, the particles 110 are graphite-based emitter particles with an average diameter of for example 4 micrometers. This type of particles is known from U.S. Pat. No. 6,097,139 mentioned earlier.

In a further step, an insulating layer 130 containing for instance SiO₂ is deposited (FIG. 1B) on the particles 110. Here, the thickness of the insulating layer 130 is such, that the layer substantially covers each emitter particle 110. The insulating layer improves the electron emission properties of the device. In a subsequent step, a conductive layer 140 is deposited on top of the insulating layer, which is optionally heated during a preselected time, for instance at 250° C. The conductive layer 140 is subsequently covered with a photo layer 150 (FIG. 1C) comprising positive photo resist.

Next, the sample is illuminated by light 160, for example UV light (FIG. 1D). The particles 110 form a mask to the incident light, so that regions 155 of the positive photo layer 150 are in the shadow of the particles 110.

After the illumination step, an etching step (FIG. 1E) is carried out wherein the sample is etched from the side of the photo layer 150. Thus, the shaded regions 155 of the photo layer 150, and the parts of the conductive layer 140 underneath these shaded regions 155 are removed. Thereby, the conductive layer 140 is provided with a pattern of apertures 135 that is self-aligned with the random distribution of the emitter particles 110.

The etching step may now be stopped, or is preferably continued so as to remove parts of the insulating layer 130 adjacent to the apertures 135 as well. Most preferably, the etching step is stopped when a thin layer of insulating material remains over the particles 110, a thickness of said thin layer being for instance 30 or 50 nanometers.

Alternatively, the insulating layer at the location of the particles 110 is removed altogether.

In a final step, the remaining part of the photo layer 150 is removed for instance by conventional rinsing with aceton and isopropanol.

For the manufacturing method to give good results, all layers should have a sufficiently high transmittivity for the light 160 that is used during the illumination step.

Preferably, the illumination is carried out using UV light. In this case, the substrate 125 may be glass that is covered with indium tin oxide (ITO) to form the cathode electrode 120, the conductive layer 140 forming the gate electrode may be ITO as well, and the insulating layer 130 is for example a glass-like SiO₂ layer.

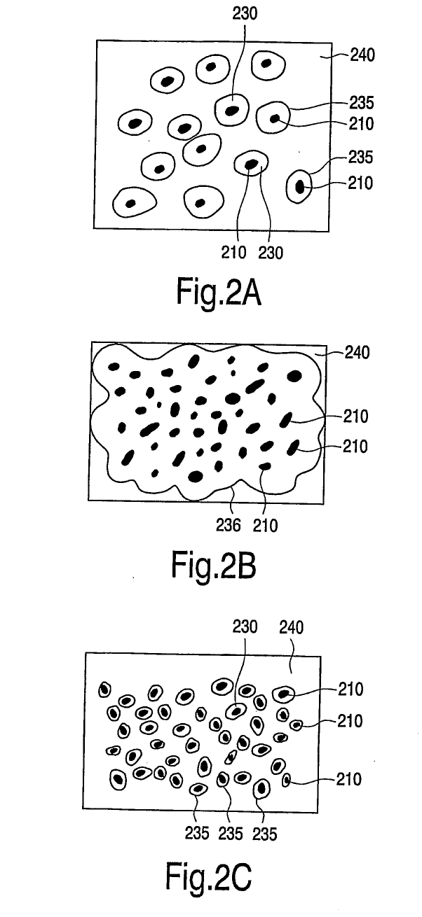

A top view of a device formed by the method is shown in FIG. 2A.

The gate electrode 240 is provided with a pattern of apertures 235, which are particularly well aligned with the emitter particles 210. In the apertures 235, the remaining part of the insulating layer 230 is visible. Generally, the emitter particles 210 are still covered with insulating material and thus they may not be visible, but here their position is indicated for clarity reasons. The conductive layer forming the gate electrode 240 is not heated, thus the diameter of the apertures etched in the conductive layer is larger than the diameter of the emitter particles 210.

However, when the density of the particles 210 is relatively high, the heating step of the conductive layer is required. Otherwise, the apertures overlap and cluster together. In this case, too large a part of the conductive layer 240 would be etched, as is illustrated in FIG. 2B where one large aperture 236 is formed. It is then not possible to apply a sufficiently strong electric field to each particle 210, so that some particles 210 show reduced emission, or no emission at all. Thereby, electron emission from the field emission device is relatively low.

Similarly, this effect may occur when emitter particles are used that have a relatively large diameter, such as 10 micrometers, or more.

By heating the conductive layer 240, preferably immediately after the depositing step, the size of the apertures that are formed by the etching step may be reduced. For instance, the layer is heated to 250° C. for one hour. Now, a device as shown in FIG. 2C is formed. Each particle 210 has its own aperture 235, which in this case has a similar or slightly larger size than the particle diameter.

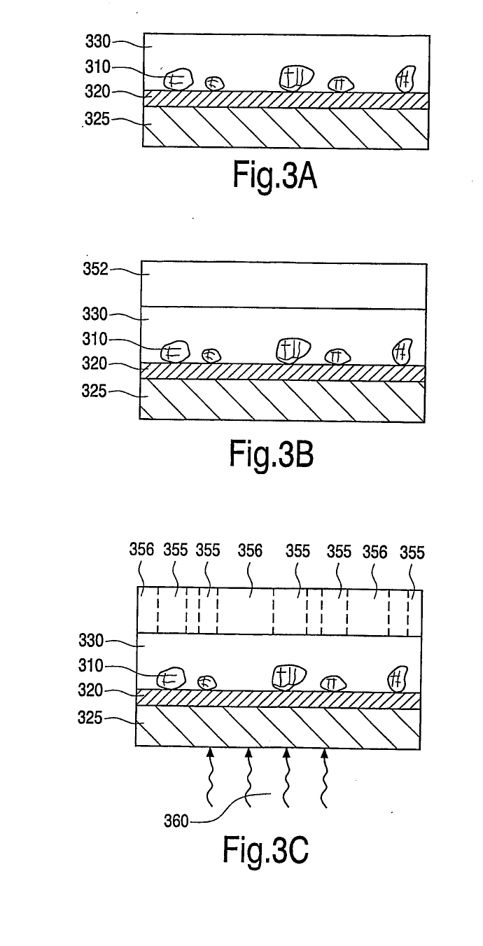

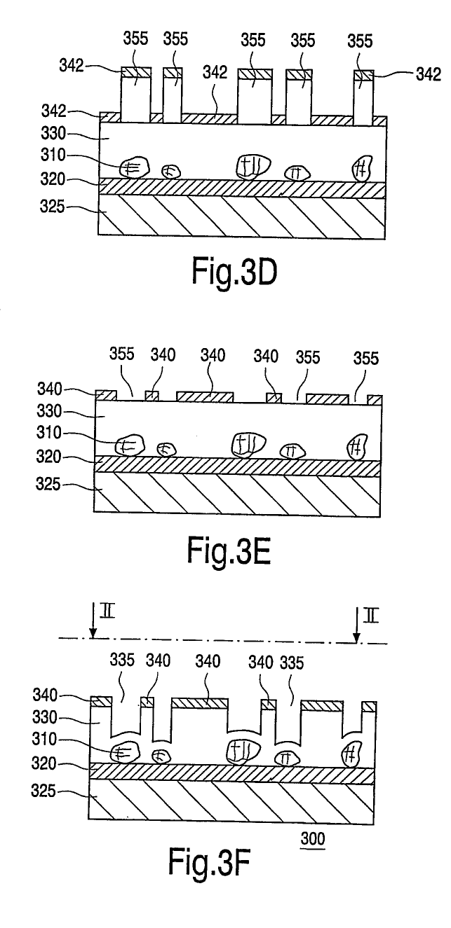

A second embodiment of the method is shown in FIGS. 3A-3F.

The second embodiment is identical to the first embodiment up to and including the step of providing the insulating layer 330.

At this stage (FIG. 3A), in a further step (FIG. 3B) a photo layer 352 comprising negative photo resist is deposited directly on top of the insulating layer 330.

In a subsequent step (FIG. 3C), the sample thus obtained is illuminated by light 360, preferably UV light. The emitter particles 310 form a mask to the incident light, so that regions 355 of the photo layer 352 are in the shadow of the particles 310.

After the illumination step, an etching step is carried out (FIG. 3D) wherein the sample is etched from the side of the photo layer 352, regions 356 adjacent to the masked regions 355 being removed. The etching step is continued until the insulating layer 330 at the location of regions 356 is exposed. Conductive material 342 suitable for forming the gate electrode, for example aluminum, is now deposited on top of the sample.

After this depositing step, the masked regions 355 of the negative photo layer 352 with the conductive material deposited on top thereof are removed. Thereby, a gate electrode 340 having apertures 335 that are self-aligned with the particles 310 is obtained, as may be seen in FIG. 3E.

If desired, the gate electrode 340 may be used as a mask for a subsequent etching step shown in FIG. 3F, whereby at least part of the insulating layer 330 at the location of the apertures 335 being removed. Preferably, this etching step is continued until a thin layer of insulating material, for example 30 or 50 micrometers, remains over the particles 310. Alternatively, this etching step is continued until the particles 310 are at least partially exposed.

A further embodiment of the field emitter device is shown in FIG. 4. This embodiment differs from the first in the choice of the emitter particles. Here, the particles comprise precursor particles 410, on which carbon nanotubes 415 are catalytically grown. The precursor particles 410 are for instance cobalt (Co) or nickel (Ni).

Carbon nanotubes are particularly good field emitters, because of the large value of the ratio between their length and diameter (typically 100 or more). The diameter of an individual carbon nanotube 415 is generally a few nanometers, which is noticeably smaller than the wavelength of the applied UV light. Therefore, in this embodiment first the precursor particles 410 are deposited, which precursor particles subsequently act as the mask during the illumination step. After forming the gate electrode 440, the carbon nanotube 415 are grown from the precursor particles 415.

Alternatively, the carbon nanotubes could be provided at the beginning of manufacturing, whereby the carbon nanotubes are provided in clusters. The size of each cluster should be chosen such that the cluster as a whole blocks the incident light during the illumination step.

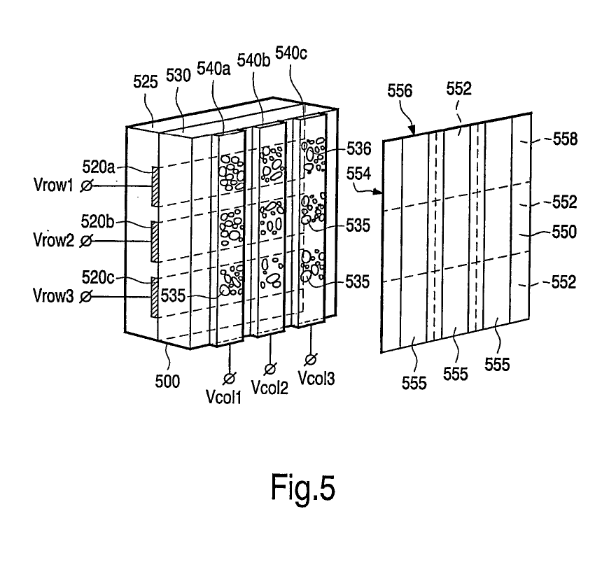

In a Field Emission Display as shown in FIG. 5, a vacuum envelope comprises a field emission device 500 according to the invention. The field emission device opposes a display screen 550 provided with phosphor tracks 555. The display screen 550 comprises picture elements 552. The field emission device 500 is used as an electron source, for generating the electrons that impinge on the phosphor tracks 555, thereby illuminating picture elements 552.

Each picture element (pixel) 552 of the display screen 550 is addressable individually, therefore the cathode electrode and gate electrode define a matrix structure. For each row 554 of pixels 552, a row cathode electrode 520a,b,c is provided, and for each column 556 of pixels 552, a column gate electrode 540a,b,c is provided.

On top of the row cathode electrodes 520a,b,c, emitter particles (not shown in this Figure) are deposited in a random distribution. The column gate electrodes 540a,b,c, are provided with a pattern of apertures 535, said pattern matching the random distribution of the emitter particles. An insulating layer 530 separates the cathode and gate electrodes.

A pixel 552 is addressed by switching on the row voltage Vrow1,2,3 of the row cathode electrode 520a,b,c corresponding to that pixel and simultaneously switching on the column voltage Vcol1,2,3 of the column gate electrode 540a,b,c, corresponding to that pixel. Then, only the emitter particles in a region at the intersection of the selected cathode and gate electrodes emit electrons, which pass through the apertures 535 of said region and land on the display screen 550.

By way of example, when row voltage Vrow1 and column voltage Vcol3 are switched on, electrons are released from a pattern of apertures indicated in the drawing by reference numeral 536, and land on the display screen 550 at selected pixel 558. Because of this, the phosphor track 555 within that selected picture element 558 illuminates, and the selected picture element 558 is visible to a viewer.

The drawings are schematic and were not drawn to scale. Whereas the invention has been described in connection with preferred embodiments, it should be understood that the invention should not be construed as being limited to the preferred embodiments. Rather, it includes all variations which could be made thereon by a skilled person, within the scope of the appended claims.

Summarizing, the invention relates to a field emission device, and a method of manufacturing same. The field emission device comprises a gate electrode which is provided with a pattern of electron-passing apertures. The gate electrode is arranged near particles distributed on a substrate, at least a part of said particles being arranged for emitting electrons. By means of the gate electrode, an electric field is applicable by means of which emitting particles emit electrons. Particularly good electron emission is obtained, because the pattern of apertures is similar to the distribution of particles on the substrate. This is achieved by means of the manufacturing method, in which the particles are used in an illumination step to mask regions of a photo layer. Thus, a pattern is obtained in the photo layer, which can be used to obtain a similar pattern in the gate electrode with relative ease.

1. A method of manufacturing a field emission device, comprising the steps of:
distributing particles (110) on a transparent substrate (125), at least a part of said particles (110) being arranged for emitting electrons;
depositing a photo layer (150);
illuminating the field emission device from the substrate side, the particles (110) shading regions (155) of the photo layer (150);
etching the shaded photo layer and
forming, near said particles, a gate electrode (140) being provided with a pattern of apertures (135) for passing electrons.

2. The method of claim 1, characterized in that the method further comprises providing a conductive layer, the photo layer (150) comprising a positive photo resist and being deposited on top of said conductive layer, and the etching step comprises further steps of
removing the shaded regions (155) of said photo layer (150) and
forming the pattern of apertures (135) in the conductive layer adjacent to the removed shaded regions (155), for forming the gate electrode (140).

3. The method of claim 2, characterized in that the method further comprises heating the conductive layer during a preselected time.

4. The method of claim 1, characterized in that the method further comprises providing an insulating layer (330) at least partially covering the particles (310), whereby the photo layer (352) comprises a negative photo resist and is deposited on top of said insulating layer (330), and the etching step comprises further steps of
removing parts (356) of said negative photo layer (352) outside the shaded regions (355) exposing parts of said insulating layer (330), and
depositing electrode material on said exposed parts of said insulating layer (330), for forming the gate electrode (340).

5. A field emission device, comprising:
a distribution of particles (110) on a substrate (125), at least a part of said particles (110) being arranged for emitting electrons;
a gate electrode (140) near said particles (110), said gate electrode (140) being provided with a pattern of apertures (135) for passing emitted electrons,
characterized in that the pattern of the apertures (135) is similar to the distribution of the particles (110).

6. The field emission device of claim 5, characterized in that an insulating layer (130) is provided between the substrate and the gate electrode (140), said insulating layer (130) at least partially covering the particles (110).

7. The field emission device of claim 6, characterized in that the insulating layer (130) is recessed substantially at the location of the particles (110).

8. The field emission device of claim 5, characterized in that the substrate (120) is transparent and comprises a transparent cathode electrode (120).

9. The field emission device of claim 7, characterized in that the cathode electrode (120) comprises indium tin oxide.

10. The field emission device of claim 5, characterized in that the particles (110) comprise a graphite-based field emitter.

11. The field emission device of claim 5, characterized in that the particles comprise carbon nanotube (415).

12. The field emission device of claim 11, characterized in that the particles further comprise precursor particles (410), from which said carbon nanotube (415) are catalytically grown.

13. A display device, comprising a field emission device according to claim 5.
